(19) United States
(12) Patent Application Publication
(10) Pub. No.: US 2015/0381184 A1
(43) Pub. Date: Dec. 31, 2015

(54) COMPOSITE ELECTRONIC COMPONENT, OSCILLATOR, ELECTRONIC APPARATUS, AND MOBILE OBJECT

(71) Applicant: Seiko Epson Corporation, Tokyo (JP)

(72) Inventors: Takumi SUZUKI, Minowa (JP); Masanori HANZAWA, Minowa (JP)

(21) Appl. No.: 14/748,682

(22) Filed: Jun. 24, 2015

(30) Foreign Application Priority Data
Jun. 26, 2014 (JP) 2014-131049

(51) Int. Cl. H03L 1/02; H03B 5/32; H03H 9/215

(52) U.S. Cl. CPC H03L 1/028; H03H 9/215; H03B 5/32

(57) ABSTRACT

A quartz crystal resonator includes a thermistor having electrodes and a quartz crystal resonator body having a package. The quartz crystal resonator body has a plurality of electrode terminals on a second principal surface of the package and the thermistor is placed at the second principal surface side of the package between the electrode terminals in a plan view or within a range surrounded by the electrode terminals. Both the electrode terminals of the quartz crystal resonator body and the electrodes of the thermistor are mounted on a substrate.

### BACKGROUND

1. Technical Field

The present invention relates to a composite electronic component, and an oscillator, an electronic apparatus, and a mobile object including the composite electronic component.

2. Related Art

In related art, as a composite electronic component including a plurality of parts, a composite electronic component including an electronic part and a sensor part fixed to the electronic part and having terminals, and mounted on a substrate by external terminals formed on an outer peripheral surface of a package of the electronic part and the terminals of the sensor part is known (e.g. Patent Document 1 (JP-A-2013-131961)).

In the composite electronic component, the terminals of the sensor part also serve as part of mounting terminals and the planar size may be made smaller compared to the case where the terminals of the sensor part and the mounting terminals are separately provided.

However, in the composite electronic component as one embodiment of Patent Document 1, the mounting terminals are provided in four corners of the package of the electronic part and the terminals of the sensor part are used as the mounting terminals. Accordingly, after mounting on the substrate, thermal stress due to a difference in coefficient of thermal expansion between the composite electronic component and the substrate is generated in a fixing part between the sensor part and the electronic part.

Here, the thermal stress is larger as closer to the outside of the package (as the distance between the mounting terminals is longer), and larger thermal stress may be concentrated on the fixing part between the sensor part and the electronic part provided closer to the outside of the package.

As a result, in the composite electronic component, the fixing part between the sensor part and the electronic part may be deteriorated, and mounting reliability on the substrate may be lower.

### SUMMARY

An advantage of some aspects of the invention is to solve at least a part of the problems described above, and the invention can be implemented as the following forms or application examples.

### Application Example 1

A composite electronic component according to this application example includes a sensor part having a terminal, and an electronic part having a package, wherein the electronic part includes a plurality of mounting terminals on a mounting surface of the package, the sensor part is placed at the mounting surface side of the package between the mounting terminals in a plan view or within a range surrounded by the mounting terminals, and both the mounting terminals of the electronic part and the terminal of the sensor part are mounted on an external member.

According to the configuration, the composite electronic component is placed at the mounting surface side of the package between the mounting terminals in the plan view or within the range surrounded by the mounting terminals, and the electronic part is mounted by the mounting terminals and the sensor part is mounted by the terminal together on the external member.

Thereby, in the composite electronic component, the mounting terminals of the electronic part may be made closer to the outside than the terminal of the sensor part.

As a result, in the composite electronic component, for example, when the sensor part is fixed to the electronic part, thermal stress generated in a fixing part between the sensor part and the electronic part after mounting on the external member such as a substrate may be suppressed to be lower than that in related art.

Further, in the composite electronic component, for example, when the sensor part is not fixed to the electronic part, thermal stress generated in the sensor part and thermal stress generated in the electronic part after mounting on the external member are independent and they can hardly affect each other.

In addition, in the composite electronic component, the terminal of the sensor part does not serve as the mounting terminal of the electronic part, and the electronic part is mounted on the external member such as a substrate reliably by the mounting terminals of itself.

Therefore, in the composite electronic component, mounting reliability on an external member such as a substrate may be made better than that in related art.

### Application Example 2

In the composite electronic component according to the application example described above, it is preferable that, in the electronic part, a resonator element is housed within the package.

According to the configuration, in the composite electronic component, the electronic part houses the resonator element within the package, and thereby, the vibrating device having a sensor function with higher mounting reliability may be provided.

### Application Example 3

In the composite electronic component according to the application example described above, it is preferable that the sensor part is a thermo-sensitive device.

According to the configuration, the sensor part is the thermo-sensitive device, and thereby, temperature compensation (temperature correction) of the electronic part with respect to the surrounding temperature changes may be performed and temperature characteristics may be improved.

### Application Example 4

In the composite electronic component according to the application example described above, it is preferable that a concave part is provided in the mounting surface and the sensor part is housed within the concave part.

According to the configuration, in the composite electronic component, the concave part is provided in the mounting surface of the package and the sensor part is housed within the concave part, and thereby, the sensor part may be protected by the concave part.

Further, in the composite electronic component, for example, when the sensor part is a thermo-sensitive device, heat transfer from the package to the sensor part is quicker due to the outside air staying within the concave part, and thereby, time lags with respect to temperature changes may be made shorter.

### Application Example 5

In the composite electronic component according to the application example described above, it is preferable that the sensor part is fixed to the package.

According to the configuration, in the composite electronic component, the sensor part is fixed to the package of the electronic part, and thereby, the sensor part and the electronic part may be integrally handled and productivity at mounting may be improved.

Further, in the composite electronic component, for example, when the sensor part is the thermo-sensitive device, heat transfer from the package to the sensor part is quicker by fixation, and thereby, time lags with respect to temperature changes may be made shorter.

### Application Example 6

In the composite electronic component according to the application example described above, it is preferable that the sensor part is fixed to the concave part and the terminal of the sensor part and the mounting terminals of the electronic part are provided on the same plane or substantially on the same plane.

According to the configuration, in the composite electronic component, the sensor part is fixed to the concave part and the terminal of the sensor part and the mounting terminals of the electronic part are provided on the same plane or substantially on the same plane, and thereby, the sensor part and the electronic part may be collectively mounted on a flat external member such as a substrate and mounting reliability may be improved.

### Application Example 7

An oscillator according to this application example includes the composite electronic component according to any one of the application examples described above.

According to the configuration, the oscillator having the configuration includes the composite electronic component according to any one of the application examples, and thereby, the oscillator having the advantage according to any one of the application examples (e.g. with higher reliability) may be provided.

### Application Example 8

An electronic apparatus according to this application example includes the composite electronic component according to any one of the application examples described above.

According to the configuration, the electronic apparatus having the configuration includes the composite electronic component according to any one of the application examples, and thereby, the electronic apparatus having the advantage according to anyone of the application examples (e.g. with higher reliability) may be provided.

### Application Example 9

A mobile object according to this application example includes the composite electronic component according to any one of the application examples described above.

According to the configuration, the mobile object having the configuration includes the composite electronic component according to any one of the application examples, and thereby, the mobile object having the advantage according to any one of the application examples (e.g. with higher reliability) may be provided.

### BRIEF DESCRIPTION OF THE DRAWINGS

The invention will be described with reference to the accompanying drawings, wherein like numbers reference like elements.

FIGS. 1A to 1C are schematic diagrams showing an overall configuration of a crystal resonator of the first embodiment, and FIG. 1A is a plan view as seen from a lid side, FIG. 1B is a sectional view along line A-A in FIG. 1A, and FIG. 1C is a plan view as seen from a bottom surface side.

FIG. 2 is a circuit diagram relating to driving of the crystal resonator containing a thermo-sensitive device housed in the crystal resonator of the first embodiment.

FIGS. 3A to 3C are schematic diagrams showing an overall configuration of a crystal resonator of modified example 1 of the first embodiment, and FIG. 3A is a plan view as seen from a lid side, FIG. 3B is a sectional view along line A-A in FIG. 3A, and FIG. 3C is a plan view as seen from a bottom surface side.

FIGS. 4A to 4C are schematic diagrams showing an overall configuration of a crystal resonator of modified example 2 of the first embodiment, and FIG. 4A is a plan view as seen from a lid side, FIG. 4B is a sectional view along line A-A in FIG. 4A, and FIG. 4C is a plan view as seen from a bottom surface side.

FIGS. 5A to 5C are schematic diagrams showing an overall configuration of a crystal resonator of the second embodiment, and FIG. 5A is a plan view as seen from a lid side, FIG. 5B is a sectional view along line A-A in FIG. 5A, and FIG. 5C is a plan view as seen from a bottom surface side.

FIGS. 6A to 6C are schematic diagrams showing an overall configuration of a crystal resonator of the third embodiment, and FIG. 6A is a plan view as seen from a lid side, FIG. 6B is a sectional view along line A-A in FIG. 6A, and FIG. 6C is a plan view as seen from a bottom surface side.

FIG. 7 is a schematic perspective view showing an oscillator.

FIG. 8 is a schematic perspective view showing a cell phone as an electronic apparatus.

FIG. 9 is a schematic perspective view showing an automobile as a mobile object.

### DESCRIPTION OF EXEMPLARY EMBODIMENTS

As below, embodiments of the invention will be explained with reference to the drawings.

### First Embodiment

First, a crystal resonator as an example of a composite electronic component will be explained.

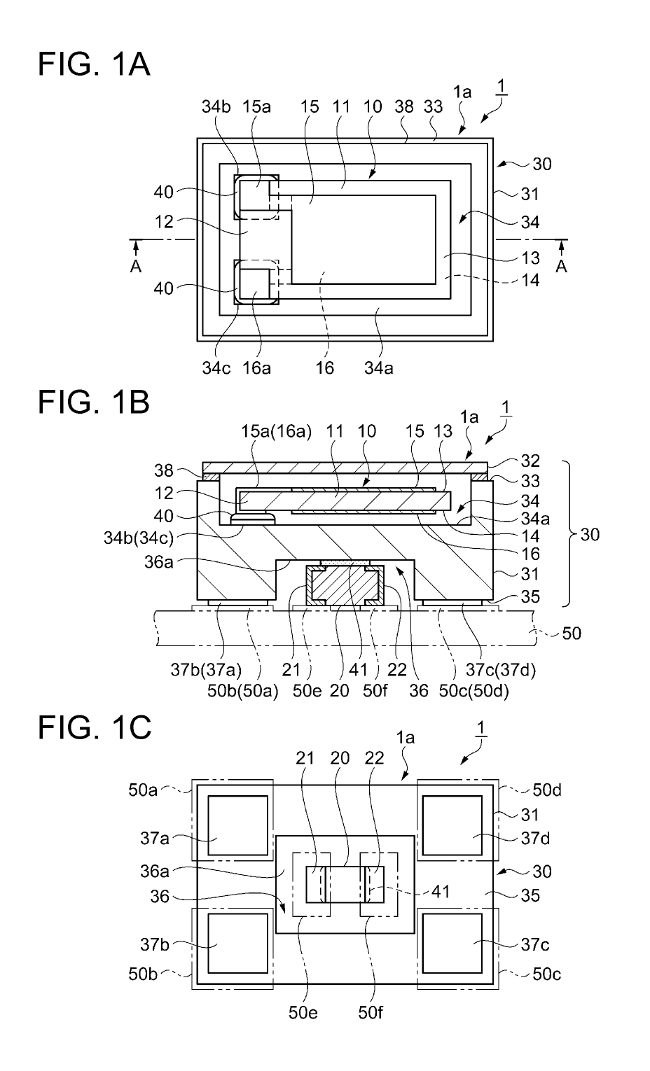

FIGS. 1A to 1C are schematic diagrams showing an overall configuration of a crystal resonator of the first embodiment. FIG. 1A is a plan view as seen from a lid side, FIG. 1B is a sectional view along line A-A in FIG. 1A, and FIG. 1C is a plan view as seen from a bottom surface side. Note that, in the following plan views as seen from the lid side including FIG. 1A, the lid is omitted. Further, to facilitate understanding, dimension ratios among respective component elements are different from reality.

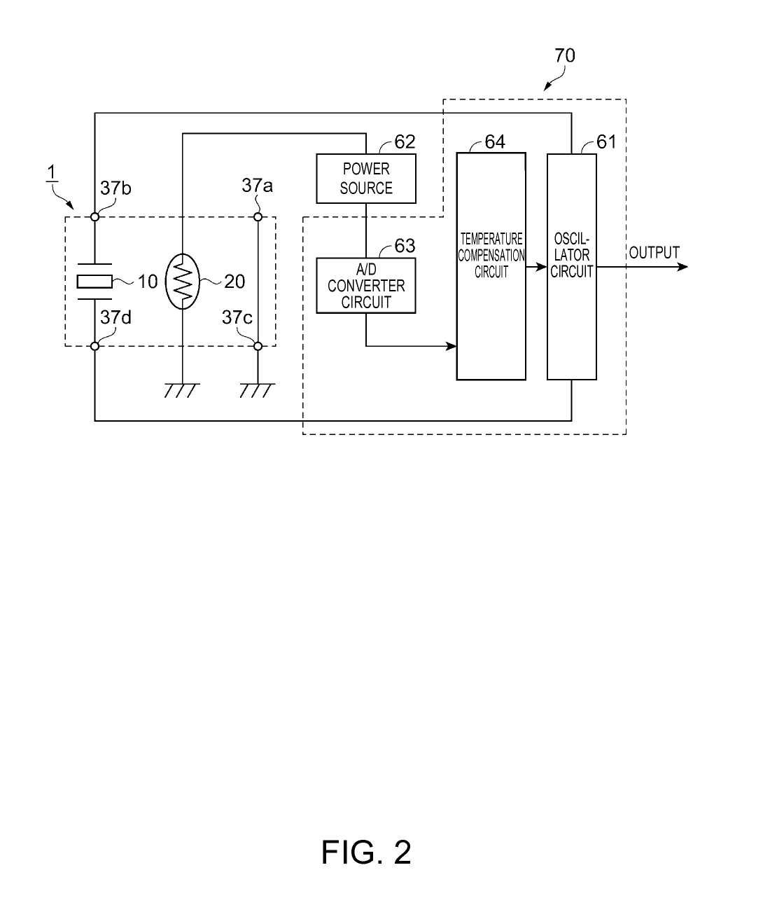

FIG. 2 is a circuit diagram relating to driving of the crystal resonator containing a thermo-sensitive device housed in the crystal resonator of the first embodiment.

As shown in FIGS. 1A to 1C, a crystal resonator 1 includes a thermistor 20 as an example of a thermo-sensitive device as a sensor part, and a crystal resonator body 1a as an electronic part having a package 30.

The crystal resonator body 1a houses a crystal vibrating reed 10 as a resonator element within the package 30.

The crystal vibrating reed 10 is of e.g. an AT-cut type in a flat plate shape cut out at a predetermined angle from an ore of crystal or the like having a planar shape formed in a nearly rectangular shape, and integrally has a vibrating part 11 for which thickness-shear vibration is excited and a base part 12 connected to the vibrating part 11.

In the crystal vibrating reed 10, extraction electrodes 15a, 16a extracted from nearly rectangular excitation electrodes 15, 16 formed on one principal surface 13 and the other principal surface 14 of the vibrating part 11 are formed in the base part 12.

The extraction electrode 15a is extracted from the excitation electrode 15 on the one principal surface 13 to the base part 12 along the longitudinal direction of the crystal vibrating reed 10 (the horizontal direction of the paper), runs around to the other principal surface 14 along the side surface of the base part 12, and extends to the vicinity of the excitation electrode 16 on the other principal surface 14.

The extraction electrode 16a is extracted from the excitation electrode 16 on the other principal surface 14 to the base part 12 along the longitudinal direction of the crystal vibrating reed 10, runs around to the one principal surface 13 along the side surface of the base part 12, and extends to the vicinity of the excitation electrode 15 on the one principal surface 13.

The excitation electrodes 15, 16 and the extraction electrodes 15a, 16a are metal films in which Au (gold) is stacked on Cr (chromium) as a foundation layer, for example.

For example, the thermistor 20 is a thermo-sensitive resistor device in a chip shape (rectangular parallelepiped shape), and a resistor having a pair of electrodes 21, 22 as terminals on both ends in the longitudinal direction and an electric resistance that largely changes with respect to temperature changes.

For the thermistor 20, e.g. a thermistor called an NTC (Negative Temperature Coefficient) thermistor having a resistance lower with rise of the temperature is used. The NTC thermistor has a resistance value proportionally changing to a change of the temperature and heavily used as a temperature sensor.

The thermistor 20 is fixed to the package 30 as will be described later, detects the temperature in the vicinity of the crystal vibrating reed 10, and thereby, fulfills the function of contributing to the correction of the frequency variations with temperature changes of the crystal vibrating reed 10 as a temperature sensor.

In order to detect the temperature in the vicinity of the crystal vibrating reed 10 more correctly as described above, the thermistor 20 is housed in the crystal resonator 1 as an external part without being integrated within an IC chip provided apart from the crystal resonator 1 in an electronic apparatus.

Here, as shown in FIG. 2, the thermistor 20 is electrically independent of the crystal vibrating reed 10 and electrically disconnected to the crystal vibrating reed 10.

Referring to FIGS. 1A to 1C, the package 30 has a package base 31 having a nearly rectangular planar shape, a lid 32 having a flat plate shape covering one side of the package base 31, and is formed in a nearly rectangular parallelepiped shape.

For the package base 31, a ceramics insulating material such as an aluminum oxide sintered compact, a mullite sintered compact, an aluminum nitride sintered compact, a silicon carbide sintered compact, or a glass ceramics sintered compact, crystal, glass, silicon (high-resistance silicon), or the like is used.

For the lid 32, the same material as that for the package base 31 or metal such as kovar, 42 Alloy, or the like is used.

Note that, when an insulating material including a resin is used for the lid 32, in order to secure a shielding property, it is preferable to use the lid 32 having a principal surface (at least a surface at the package base 31 side) covered by plating of a metal or a conducting film.

A first concave part 34 in which the crystal vibrating reed 10 is housed is provided on a first principal surface 33 as one principal surface of the package base 31, and a second concave part 36 in which the thermistor 20 is housed is provided on a second principal surface 35 as a mounting surface, the other principal surface opposite to the first principal surface 33.

The first concave part 34 and the second concave part 36 have nearly rectangular planar shapes and are provided nearly at the centers of the first principal surface 33 and the second principal surface 35, respectively. Note that, in the crystal resonator 1, the first concave part 34 and the second concave part 36 of the package base 31 are provided to overlap with each other in the plan view, and thereby, the package 30 is downsized.

Internal terminals 34b, 34c are provided in positions facing the extraction electrodes 15a, 16a of the crystal vibrating reed 10 on a bottom surface 34a of the first concave part 34 of the package base 31.

In the crystal vibrating reed 10, the extraction electrodes 15a, 16a are bonded to the internal terminals 34b, 34c via epoxy, silicon, or polyimide conducting adhesive agents 40 mixed with a conducting material such as a metal filler.

In the crystal resonator 1, when the crystal vibrating reed 10 is bonded to the internal terminals 34b, 34c of the package base 31, the first concave part 34 of the package base 31 is covered by the lid 32, the package base 31 and the lid 32 are bonded by a bonding member 38 including a seaming ring (including a cladding material formed by bonding a plate-like brazing filler material to the lid 32), low-melting-point glass, and an adhesive agent, and thereby, the first concave part 34 of the package base 31 is air-tightly sealed.

Note that the interior of the air-tightly sealed first concave part 34 of the package base 31 is in a reduced-pressure vacuum state (a state at a higher degree of vacuum) or a state filled with an inert gas including nitrogen, helium, and argon.

In four corners of the second principal surface 35 of the package base 31, electrode terminals 37a, 37b, 37c, 37d as rectangular mounting terminals are respectively provided.

Of the four electrode terminals 37a to 37d, for example, two electrode terminals 37b, 37d located in one pair of opposing corners are electrically connected to the internal terminals 34b, 34c bonded to the extraction electrodes 15a, 16a of the crystal vibrating reed 10 by internal wiring (not shown). Specifically, for example, the electrode terminal 37b is electrically connected to the internal terminal 34b and the electrode terminal 37d is electrically connected to the internal terminal 34d.

It is preferable that the two electrode terminals 37a, 37c located in the other pair of opposing corners are electrically connected to the lid 32 by internal wiring (not shown). Here, the electrode terminals 37a, 37c are electrically connected to the lid 32 and both serve as ground terminals (GND terminals).

Note that, for the electrical connection between the electrode terminals 37a, 37c and the lid 32, a conducting film provided in a castellation (concave part, not shown) formed along the thickness direction of the package base 31 may be used on an outer corner of the package base 31.

For example, the internal terminals 34b, 34c and the electrode terminals 37a to 37d of the package base 31 are formed by metal films in which respective films of Ni (nickel), Au (gold), or the like are stacked on a metallization layer of W (tungsten), Mo (Molybdenum), or the like by plating or the like.

Here, the thermistor 20 is placed at the side of the second principal surface 35 as the mounting surface of the package 30 (package base 31) within the range surrounded by the electrode terminals 37a to 37d in the plan view.

The thermistor 20 is housed in the second concave part 36 provided in the second principal surface 35 of the package 30, and fixed to the bottom surface 36a of the second concave part 36 using e.g., an epoxy, silicone, or polyimide insulating adhesive agent 41.

The thermistor 20 is provided so that the longitudinal direction connecting the electrode 21 and the electrode 22 may be along the longitudinal direction of the package 30 (the horizontal direction of the paper).

In this regard, in the crystal resonator 1, the depth of the second concave part 36 and the amount of application of the insulating adhesive agent 41 are adjusted so that the electrodes 21, 22 of the thermistor 20 and the electrode terminals 37a to 37d of the package base 31 may be provided on the same plane or substantially on the same plane.

Thereby, in the crystal resonator 1, the crystal resonator body 1a may be mounted by the electrode terminals 37a to 37d and the thermistor 20 may be mounted by the electrodes 21, 22 together on a substrate 50 as an external member.

Specifically, as shown in FIGS. 1B and 1C, the electrode terminals 37a to 37d of the crystal resonator body 1a may be mounted on mounting lands 50a to 50d of the flat substrate 50, and the electrodes 21, 22 of the thermistor 20 may be mounted on mounting lands 50e, 50f.

As shown in FIG. 2, in the crystal resonator 1, for example, thickness-shear vibration is excited by drive signals applied via the electrode terminals 37b, 37d from an oscillator circuit 61 integrated in an IC chip 70 of the electronic apparatus and the crystal vibrating reed 10 resonates (oscillates) at a predetermined frequency, and resonance signals (oscillation signals) are output from the electrode terminals 37b, 37d.

In this regard, in the crystal resonator 1, the thermistor 20 detects the temperature in the vicinity of the crystal vibrating reed 10 as the temperature sensor, converts it into a change of a voltage value supplied from a power source 62, and outputs it as a detection signal.

For example, the output detection signal is A/D-converted by an A/D converter circuit 63 integrated within the IC chip 70 of the electronic apparatus and input to a temperature compensation circuit 64. Then, the temperature compensation circuit 64 outputs a correction signal based on temperature compensation data to the oscillator circuit 61 in response to the input detection signal.

The oscillator circuit 61 applies a drive signal corrected based on the input correction signal to the crystal vibrating reed 10, and corrects the resonance frequency of the crystal vibrating reed 10 varying with temperature changes to a predetermined frequency. The oscillator circuit 61 outputs the corrected frequency to the outside.

As described above, in the crystal resonator 1 as the composite electronic component of the first embodiment, the thermistor 20 as the sensor part is placed at the side of the second principal surface 35 as the mounting surface of the package 30 within the range surrounded by the electrode terminals 37a to 37d in the plan view. Further, in the crystal resonator 1, both the electrode terminals 37a to 37d of the crystal resonator body 1a as the electronic part and the electrodes 21, 22 as the terminals of the thermistor 20 are mounted together on the substrate 50 as the external member.

Thereby, in the crystal resonator 1, the electrode terminals 37a to 37d of the quartz crystal resonator body 1a may be located at the outer side than the electrodes 21, 22 of the thermistor 20.

As a result, in the quartz crystal resonator 1, when the thermistor 20 is fixed to the quartz crystal resonator body 1a, thermal stress generated in the fixing part between the thermistor 20 and the quartz crystal resonator body 1a (the part in which they are fixed by the insulating adhesive agent 41) after mounting on the external member such as the substrate 50 may be suppressed to be lower than that in related art.

In addition, in the quartz crystal resonator 1, the electrodes 21, 22 of the thermistor 20 do not serve as the mounting terminals of the quartz crystal resonator body 1a, and the quartz crystal resonator body 1a is reliably mounted on the external member such as the substrate 50 by the electrode terminals 37a to 37d as the mounting terminals of itself.

Thereby, the mounting reliability of the quartz crystal resonator 1 on the external member such as the substrate 50 may be improved to be higher than that in related art.

Further, in the quartz crystal resonator 1, the quartz crystal resonator body 1a houses the quartz crystal vibrating reed 10 as the resonator element within the package 30, and thereby, the quartz crystal resonator with the temperature sensor (thermistor 20) as the vibrating device having a sensor function with higher mounting reliability may be provided.

Furthermore, in the quartz crystal resonator 1, the sensor part is the thermistor 20 as the thermo-sensitive device, and thereby, temperature compensation (temperature correction) of the quartz crystal resonator body 1a with respect to the surrounding temperature changes may be performed and temperature characteristics may be improved.

In the quartz crystal resonator 1, the second concave part 36 as the concave part is provided in the second principal surface 35 of the package 30 and the thermistor 20 is housed within the second concave part 36, and thereby, the thermistor 20 may be protected by the second concave part 36.

Further, in the quartz crystal resonator 1, heat transfer from the package 30 to the thermistor 20 is quicker due to the outside air staying within the second concave part 36 than that in the case without the second concave part 36, and thereby, time lags with respect to temperature changes may be made shorter.

Furthermore, in the quartz crystal resonator 1, the thermistor 20 is fixed to the package 30 of the quartz crystal resonator body 1a, and thereby, the thermistor 20 and the quartz crystal resonator body 1a may be integrally handled and productivity at mounting on an external member including the substrate 50 may be improved.

In the quartz crystal resonator 1, the thermistor 20 is fixed to the package 30 and heat transfer from the package 30 to the thermistor 20 is quicker, and thereby, time lags with respect to temperature changes may be made shorter.

Further, in the quartz crystal resonator 1, the thermistor 20 is fixed to the second concave part 36 and the electrodes 21, 22 of the thermistor 20 and the electrode terminals 37a to 37d of the quartz crystal resonator body 1a are provided on the same plane or substantially on the same plane, and thereby, the thermistor 20 and the quartz crystal resonator body 1a may be easily and collectively mounted on a flat external member including the substrate 50.

Furthermore, in the quartz crystal resonator 1, the first principal surface 33 side is air-tightly sealed by the metal lid 32 covering the quartz crystal vibrating reed 10, and the electrode terminals 37a, 37c are electrically connected to the lid 32, and thereby, shielding performance with respect to noise and static electricity from outside may be improved.

In addition, in the quartz crystal resonator 1, both of the electrode terminals 37a, 37c electrically connected to the lid 32 are the ground terminals (GND terminals) and the electrode terminals 37a, 37c are grounded (earthed) via an external member including the substrate 50, and thereby, the shielding performance may be further improved.

Note that the quartz crystal resonator 1 may have a configuration in which the second concave part 36 may be expanded and the electrode terminals 37a to 37d parts of the package base 31 are respectively left in columnar shapes.

### Modified Example 1

Next, modified example 1 of the first embodiment will be explained.

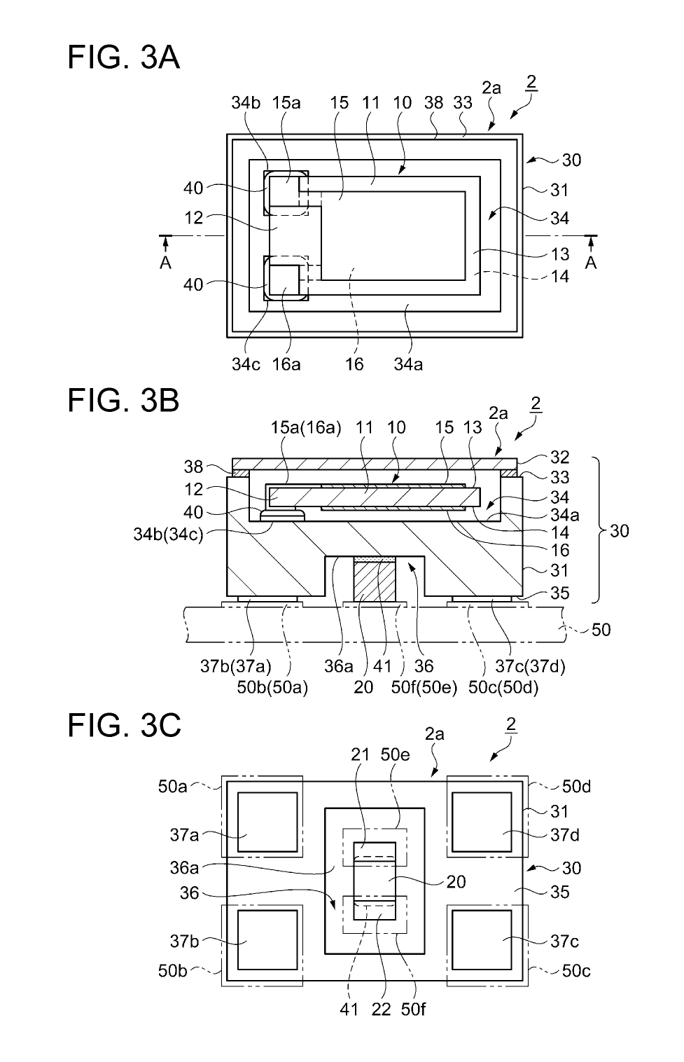

FIGS. 3A to 3C are schematic diagrams showing an overall configuration of a quartz crystal resonator of modified example 1 of the first embodiment. FIG. 3A is a plan view as seen from a lid side, FIG. 3B is a sectional view along line A-A in FIG. 3A, and FIG. 3C is a plan view as seen from a bottom surface side.

Note that the same signs are assigned to the parts in common with the first embodiment and the detailed explanation will be omitted, and the parts different from the first embodiments will be centered for explanation.

As shown in FIGS. 3A to 3C, a quartz crystal resonator 2 of modified example 1 is different from the first embodiment in the placement orientation of the thermistor 20.

In the quartz crystal resonator 2, the thermistor 20 is placed so that the longitudinal direction connecting the electrode 21 and the electrode 22 of the thermistor 20 may be along a direction intersecting with (here, orthogonal to) the longitudinal direction of a quartz crystal resonator body 2a (the horizontal direction of the paper).

Thereby, in the quartz crystal resonator 2, in addition to the advantages of the first embodiment, reduction of fixing strength (bonding strength) of the thermistor 20 with warpage of the package base 31, which tends to largely warp in the longitudinal direction, may be suppressed.

### Modified Example 2

Next, modified example 2 of the first embodiment will be explained.

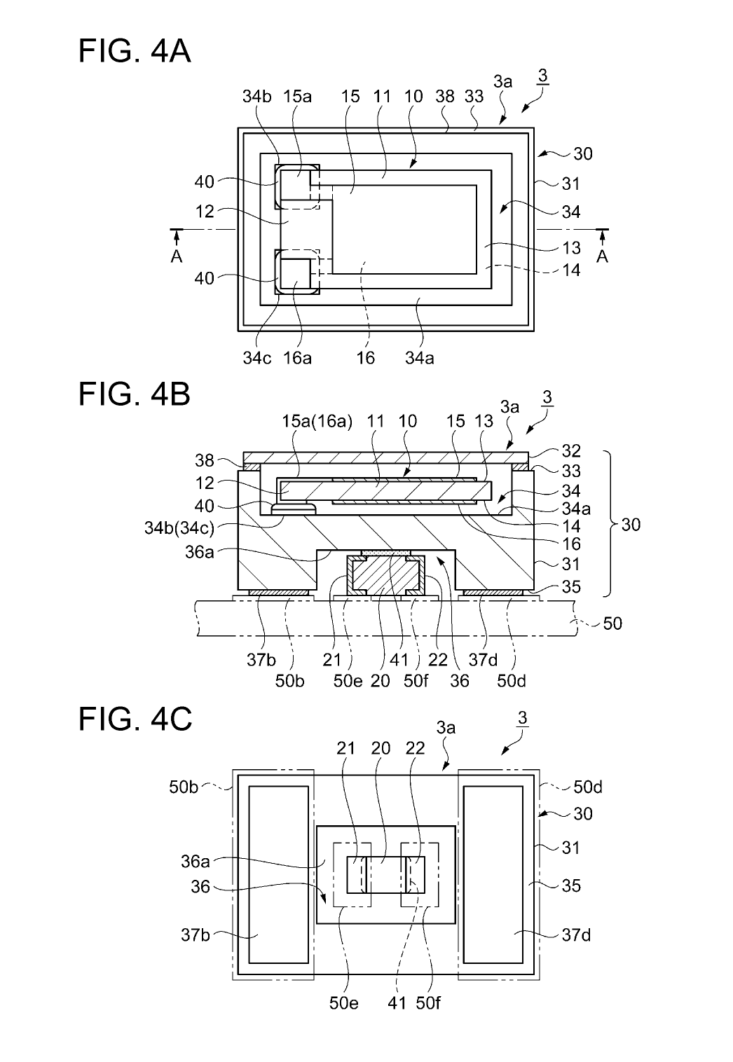

FIGS. 4A to 4C are schematic diagrams showing an overall configuration of a quartz crystal resonator of modified example 2 of the first embodiment. FIG. 4A is a plan view as seen from a lid side, FIG. 4B is a sectional view along line A-A in FIG. 4A, and FIG. 4C is a plan view as seen from a bottom surface side.

Note that the same signs are assigned to the parts in common with the first embodiment and the detailed explanation will be omitted, and the parts different from the first embodiments will be centered for explanation.

As shown in FIGS. 4A to 4C, a quartz crystal resonator 3 of modified example 2 is different from the first embodiment in the number of electrode terminals.

In the quartz crystal resonator 3, the electrode terminals 37a, 37c of a quartz crystal resonator body 3a are eliminated and the electrode terminals 37b, 37d extend to the sides where the electrode terminals 37a, 37c had been provided in rectangular shapes. Thereby, the thermistor 20 is provided between the electrode terminals 37b, 37d.

Further, in the quartz crystal resonator 3, the electrode terminals 37b, 37d are mounted on mounting lands 50b, 50d having rectangular shapes of the substrate 50.

Thereby, in the quartz crystal resonator 3, in addition to the advantages of the first embodiment, the electrode terminals are only the two electrode terminals 37b, 37d and the planar size may be further downsized compared to the first embodiment with the four terminals.

Note that the configuration of modified example 2 may be applied to modified example 1 and the following respective embodiments.

### Second Embodiment

Next, a quartz crystal resonator of the second embodiment will be explained.

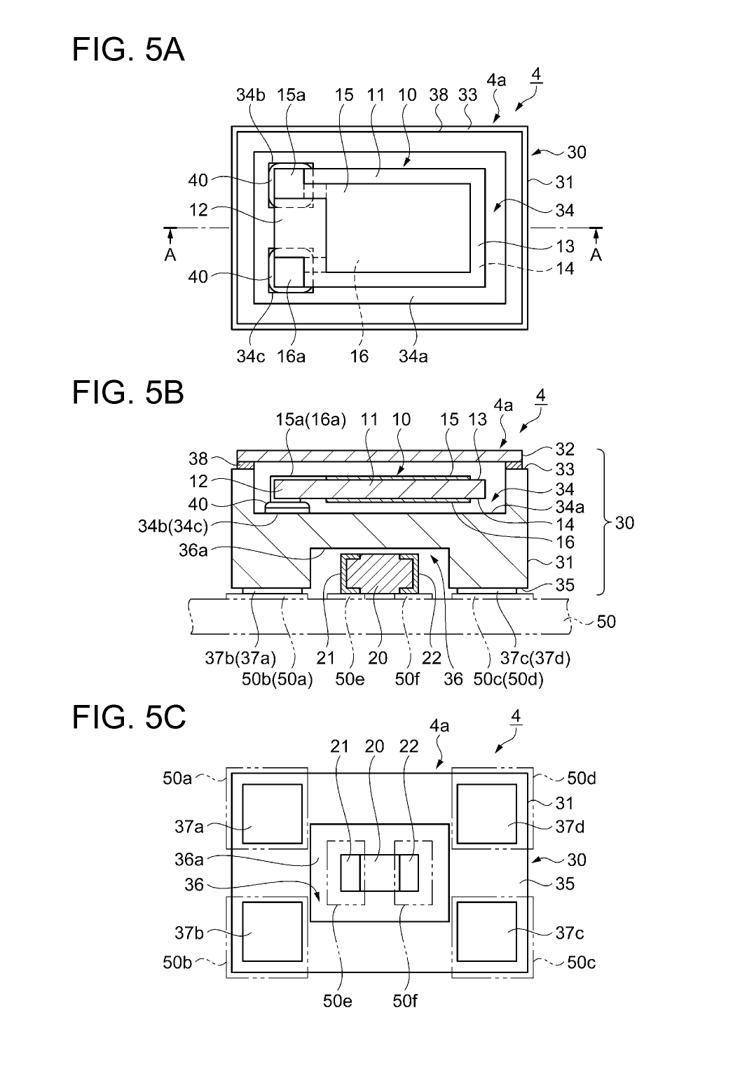

FIGS. 5A to 5C are schematic diagrams showing an overall configuration of a quartz crystal resonator of the second embodiment. FIG. 5A is a plan view as seen from a lid side, FIG. 5B is a sectional view along line A-A in FIG. 5A, and FIG. 5C is a plan view as seen from a bottom surface side.

Note that the same signs are assigned to the parts in common with the first embodiment and the detailed explanation will be omitted, and the parts different from the first embodiments will be centered for explanation.

As shown in FIGS. 5A to 5C, a quartz crystal resonator of the second embodiment is different from the first embodiment in that the thermistor 20 is not fixed to a quartz crystal resonator body 4a.

In the quartz crystal resonator 4, the thermistor 20 is housed within the second concave part 36 of the package base 31 of the quartz crystal resonator body 4a, but not fixed to the second concave part 36.

Accordingly, in the quartz crystal resonator 4, the thermistor 20 is not fixed to the quartz crystal resonator body 4a, and thereby, thermal stress generated in the thermistor 20 and thermal stress generated in the quartz crystal resonator body 4a after mounting on an external member including the substrate 50 are independent and they can hardly affect each other.

As a result, in the quartz crystal resonator 4, mounting reliability on an external member including the substrate 50 may be further improved compared to that in related art and the first embodiment.

### Third Embodiment

Next, a quartz crystal resonator of the third embodiment will be explained.

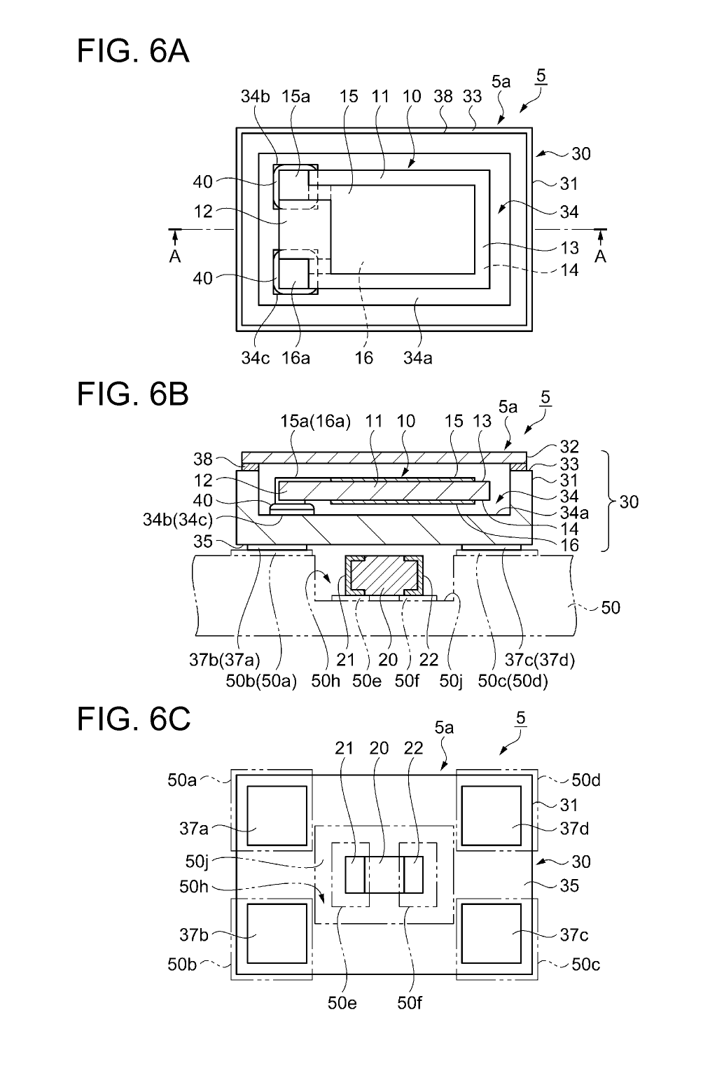

FIGS. 6A to 6C are schematic diagrams showing an overall configuration of a quartz crystal resonator of the third embodiment. FIG. 6A is a plan view as seen from a lid side, FIG. 6B is a sectional view along line A-A in FIG. 6A, and FIG. 6C is a plan view as seen from a bottom surface side.

Note that the same signs are assigned to the parts in common with the first embodiment and the detailed explanation will be omitted, and the parts different from the first embodiments will be centered for explanation.

As shown in FIGS. 6A to 6C, a quartz crystal resonator 5 of the third embodiment is different from the first embodiment in that the second concave part 36 is not provided in the second principal surface 35 of the package base 31 of a quartz crystal resonator body 5a. In the quartz crystal resonator 5, the package base 31 is formed to be thinner by the thickness of the second concave part.

The thermistor 20 is placed at the second principal surface 35 side within the range surrounded by the electrode terminals 37a to 37d in the plan view even when the second concave part 36 is not provided. Further, the thermistor 20 is not fixed to the package base 31.

In the quartz crystal resonator 5, a concave part 50h that can house the thermistor 20 is provided in the substrate 50, mounting lands 50e, 50f are provided on a bottom surface 50j of the concave part 50h, and thereby, the quartz crystal resonator may be mounted on an external member including the substrate 50.

Specifically, the electrodes 21, 22 of the thermistor 20 are mounted on the mounting lands 50e, 50f of the concave part 50h and the electrode terminals 37a to 37d of the quartz crystal resonator body 5a are mounted on the mounting lands 50a to 50d.

In this regard, the concave part 50h is formed in a depth that the thermistor 20 does not contact with the quartz crystal resonator body 5a.

Thereby, in the quartz crystal resonator 5, the second concave part 36 is not necessary for the package base 31, and the manufacture of the package base 31 is easier.

Note that, in the quartz crystal resonator 5, the thermistor 20 may be fixed to the package base 31. Thereby, in the quartz crystal resonator 5, the thermistor 20 and the quartz crystal resonator body 5a may be integrally handled and productivity at mounting on an external member including the substrate 50 may be improved.

### Oscillator

Next, an oscillator including the above described quartz crystal resonator as the composite electronic component will be explained.

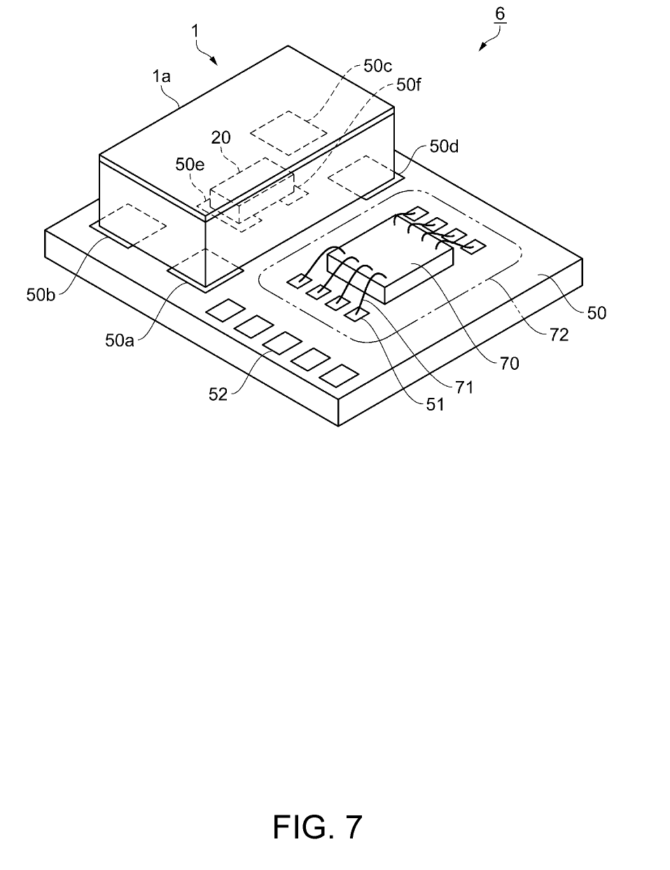

FIG. 7 is a schematic perspective view showing an oscillator.

As shown in FIG. 7, an oscillator 6 is of a module type and includes the substrate 50, the quartz crystal resonator 1 (or one of the quartz crystal resonators 2 to 5) mounted on the substrate 50, and the IC chip 70 containing an oscillator circuit etc.

The IC chip 70 contains the oscillator circuit 61, the A/D converter circuit 63, the temperature compensation circuit 64, etc. shown in the circuit diagram of FIG. 2.

The IC chip 70 is mounted on the substrate 50 having a rectangular flat plate shape and connection pads (not shown) and internal terminals 51 of the substrate 50 are connected by metal wires 71.

The IC chip 70 with the metal wires 71 is molded (coated) by a molding material 72 (its contour shown by a dashed-two dotted line) such as an epoxy resin.

The quartz crystal resonator 1 is provided near the IC chip 70 on the side, the quartz crystal resonator body 1a is mounted on the mounting lands 50a to 50d of the substrate 50, and the thermistor 20 is mounted on the mounting lands 50e, 50f.

On the substrate 50, a plurality of input/output terminals 52 are provided on one end, and the internal terminals 51, the mounting lands 50a to 50f, and the input/output terminals 52 are connected to one another by wiring (not shown).

As shown in FIGS. 2 and 7, in the oscillator 6, the quartz crystal vibrating reed 10 resonates (oscillates) at a predetermined frequency and outputs resonance signals (oscillation signals) by the drive signal applied to the quartz crystal resonator 1 from the oscillator circuit 61 within the IC chip 70 activated by external input from the input/output terminals 52.

In this regard, in the quartz crystal resonator 1, the thermistor 20 detects the temperature in the vicinity of the quartz crystal vibrating reed 10 as the temperature sensor, converts it into a change of a voltage value supplied from the external power source 62, and outputs it as a detection signal.

The output detection signal is A/D-converted by the A/D converter circuit 63 and input to the temperature compensation circuit 64. Then, the temperature compensation circuit 64 outputs a correction signal based on temperature compensation data to the oscillator circuit 61 in response to the input detection signal.

The oscillator circuit 61 applies a drive signal corrected based on the input correction signal to the quartz crystal vibrating reed 10, and corrects the resonance frequency of the quartz crystal vibrating reed 10 varying with temperature changes to a predetermined frequency.

The oscillator 6 amplifies the oscillation signal at the corrected frequency and outputs it from the input/output terminals 52 to the outside.

As described above, the oscillator 6 includes the quartz crystal resonator 1 (or one of the quartz crystal resonators 2 to 6) as the composite electronic component, and thereby, the oscillator with higher reliability having the advantages described in the respective embodiments and the respective modified examples may be provided.

Note that, in the oscillator 6, the IC chip 70 may be contained within the quartz crystal resonator body 1a of the quartz crystal resonator 1. According to the configuration, the oscillator 6 may be downsized compared to the above described module type.

Note that the IC chip 70 may be formed by flip-chip mounting of flipping and using bumps.

Further, the oscillator 6 may use a lead frame in place of the substrate 50. In this case, the whole is transfer-molded and the parts corresponding to the input/output terminals 52 may be exposed as lead terminals.

### Electronic Apparatuses

Next, electronic apparatuses including the above described quartz crystal resonators as the composite electronic components will be explained by taking a cell phone as an example.

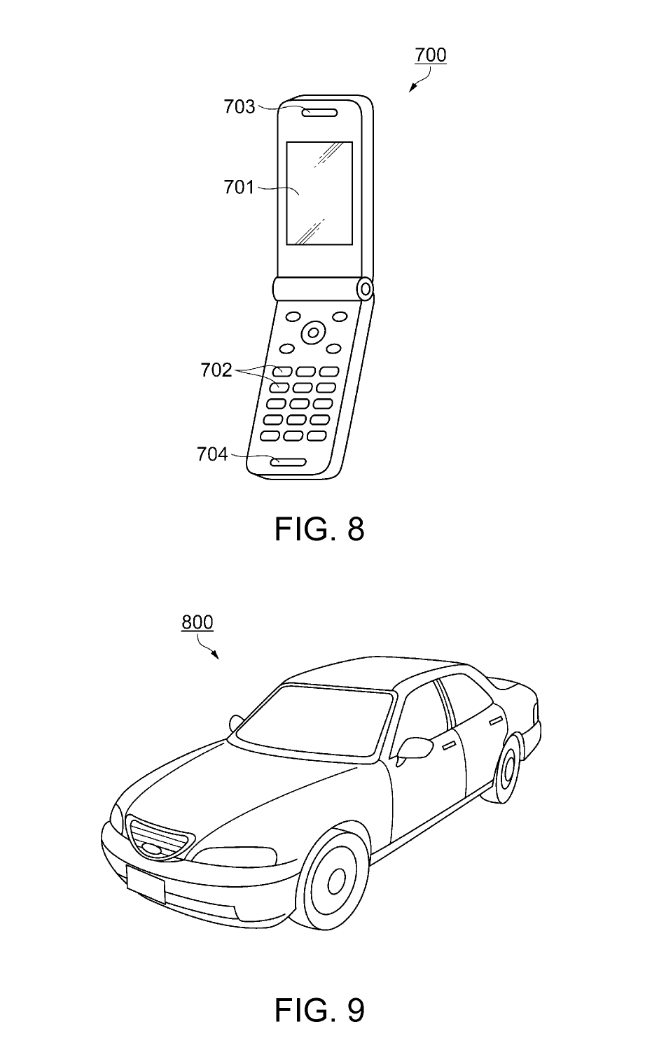

FIG. 8 is a schematic perspective view showing a cell phone as the electronic apparatus.

A cell phone 700 includes the quartz crystal resonator as the composite electronic component described in the respective embodiments and the respective modified examples.

The cell phone 700 shown in FIG. 8 uses one of the above described quartz crystal resonators (1 to 5) as a timing device of e.g., a reference clock oscillation source, and further includes a liquid quartz crystal device 701, a plurality of operation buttons 702, an ear piece 703, and a mouthpiece 704. Note that the form of the cell phone is not limited to the shown type, and may be a form of the so-called smartphone type.

The above described composite electronic components of the quartz crystal resonator or the like may be applied as timing devices not only to the cell phones but also to electronic apparatuses including electronic books, personal computers, televisions, digital still cameras, video cameras, video recorders, navigation systems, pagers, personal digital assistances, calculators, word processors, work stations, videophones, POS terminals, game machines, medical apparatuses (e.g., electronic thermometers, sphygmomanometers, blood glucose meters, electrocardiographic measurement apparatuses, ultrasonic diagnostic apparatuses, or electronic endoscopes), fish finders, various measurement instruments, meters and gauges, and flight simulators. In any case, the electronic apparatuses with higher reliability having the advantages explained in the respective embodiments and the respective modified examples may be provided.

### Mobile Object

Next, a mobile object including the above described composite electronic component will be explained by taking an automobile as an example.

FIG. 9 is a schematic perspective view showing an automobile as the mobile object.

An automobile 800 includes the quartz crystal resonator as the composite electronic component described in the respective embodiments and the respective modified examples.

The automobile 800 uses one of the above described quartz crystal resonators (1 to 5) as a timing device of e.g., a reference clock oscillation source of various mounted electronically-controlled apparatuses (e.g. electronically-controlled fuel injection apparatus, electronically-controlled ABS apparatus, electronically-controlled constant-speed traveling apparatus, etc.)

According to the configuration, the automobile 800 includes the quartz crystal resonator, and thereby, may have the advantages explained in the respective embodiments and the respective modified examples and provide highly reliable and better performance.

The above described composite electronic components including the quartz crystal resonators may be applied as timing devices of e.g. reference clock oscillation sources not only to the automobile 800 but also to mobile objects including self-propelled robots, self-propelled transportation apparatuses, trains, ships, airplanes, and artificial satellites. In any case, the mobile objects with higher reliability having the advantages explained in the respective embodiments and the respective modified examples may be provided.

Note that the shape of the vibrating reed of the quartz crystal resonator is not limited to the illustrated flat-plate type, but may be a type thicker at the center and thinner at the periphery (e.g. convex type, bevel type, mesa type), a type thinner at the center and thicker at the periphery (e.g. inverse mesa type), or a tuning-fork shape.

Note that the material of the vibrating reed is not limited to quartz crystal, but may be a piezoelectric material such as lithium tantalate (LiTaO₃), lithium tetraborate (Li₂B₄O₇), lithium niobate (LiNbO₃), lead zirconate titanate (PZT), zinc oxide (ZnO), aluminum nitride (AlN) or a semiconductor such as silicon (Si).

Further, the method of driving the thickness-shear vibration may be not only the method using the piezoelectric effect of the piezoelectric material but also electrostatic driving using Coulomb force.

The entire disclosure of Japanese Patent Application No. 2014-131049, filed Jun. 26, 2014 is expressly incorporated by reference herein.

What is claimed is:

1. A composite electronic component comprising:
a sensor part having a terminal; and
an electronic part having a package,
wherein the electronic part includes a plurality of mounting terminals provided on a mounting surface of the package,
the sensor part is placed at the mounting surface side of the package between the plurality of mounting terminals in a plan view or within a range surrounded by the mounting terminals, and
both the mounting terminals of the electronic part and the terminal of the sensor part are mounted on an external member.

2. The composite electronic component according to claim 1, wherein, in the electronic part, a resonator element is housed within the package.

3. The composite electronic component according to claim 1, wherein the sensor part is a thermo-sensitive device.

4. The composite electronic component according to claim 1, wherein a concave part is provided at the mounting surface side of the package and the sensor part is housed within the concave part.

5. The composite electronic component according to claim 1, wherein the sensor part is fixed to the package.

6. The composite electronic component according to claim 4, wherein the sensor part is fixed to the concave part and the terminal of the sensor part and the mounting terminals of the electronic part are provided on the same plane or substantially on the same plane.

7. An oscillator including the composite electronic component according to claim 1.

8. An electronic apparatus including the composite electronic component according to claim 1.

9. A mobile object including the composite electronic component according to claim 1.
